(19) United States
(12) Patent Application Publication
(10) Pub. No.: US 2026/0118203 A1
(43) Pub. Date: Apr. 30, 2026

(54) LEAK DETECTION IN A DIRECT LIQUID COOLING SYSTEM VIA DETECTION OF A VOLATILE COMPOUND IN COOLANT LIQUID

(71) Applicant: DELL PRODUCTS L.P., Round Rock, TX (US)

(72) Inventors: Kevin Mundt, Livingston, TX (US); James Utz, Georgetown, TX (US)

(21) Appl. No.: 18/931,282

(22) Filed: Oct. 30, 2024

(51) Int. Cl. G01M 3/20; H05K 7/20

(52) U.S. Cl. CPC G01M 3/20; H05K 7/20254; H05K 7/20272

(57) ABSTRACT

A liquid cooling system includes a tube to carry a liquid coolant. A liquid coolant includes ferromagnetic particles. The coolant liquid flow motor is provided around a perimeter of the tube, and induces a vortex in the liquid coolant.

### CROSS REFERENCE TO RELATED APPLICATIONS

Related subject matter is contained in co-pending U.S. patent application Ser. No. 14/______ (DC-139471) entitled “Leak Detection in a Direct Liquid Cooling System Via Carbonation of the Coolant Liquid,” filed of even date herewith, the disclosure of which is hereby incorporated by reference.

Related subject matter is contained in co-pending U.S. patent application Ser. No. 14/______ (DC-139494) entitled “Leak Detection in a Direct Liquid Cooling System Via the Detection of Humidity,” filed of even date herewith, the disclosure of which is hereby incorporated by reference.

### FIELD OF THE DISCLOSURE

This disclosure relates to information handling systems, and more particularly relates to leak detection in a direct liquid cooling (DLC) system in an information handling system via detection of a volatile compound in the coolant liquid.

### BACKGROUND

As the value and use of information continues to increase, individuals and businesses seek additional ways to process and store information. One option is an information handling system. An information handling system generally processes, compiles, stores, and/or communicates information or data for business, personal, or other purposes. Because technology and information handling needs and requirements may vary between different applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, reservations, enterprise data storage, or global communications. In addition, information handling systems may include a variety of hardware and software resources that may be configured to process, store, and communicate information and may include one or more computer systems, data storage systems, and networking systems.

### SUMMARY

A liquid cooling system may include a tube and a coolant liquid flow motor. The tube may carry a liquid coolant. The liquid coolant may include ferromagnetic particles. The coolant liquid flow motor may be provided around the tube, and may induce a vortex in a flow of the liquid coolant.

### BRIEF DESCRIPTION OF THE DRAWINGS

It will be appreciated that for simplicity and clarity of illustration, elements illustrated in the Figures have not necessarily been drawn to scale. For example, the dimensions of some of the elements are exaggerated relative to other elements. Embodiments incorporating teachings of the present disclosure are shown and described with respect to the drawings presented herein, in which:

FIG. 1 is a block diagram of a direct liquid cooling (DLC) system according to an embodiment of the present disclosure;

FIG. 2 illustrates a DLC system according to another embodiment of the present disclosure; and

FIG. 3 is a block diagram illustrating a generalized information handling system according to another embodiment of the present disclosure;

The use of the same reference symbols in different drawings indicates similar or identical items.

### DETAILED DESCRIPTION OF DRAWINGS

The following description in combination with the Figures is provided to assist in understanding the teachings disclosed herein. The following discussion will focus on specific implementations and embodiments of the teachings. This focus is provided to assist in describing the teachings, and should not be interpreted as a limitation on the scope or applicability of the teachings. However, other teachings can certainly be used in this application. The teachings can also be used in other applications, and with several different types of architectures, such as distributed computing architectures, client/server architectures, or middleware server architectures and associated resources.

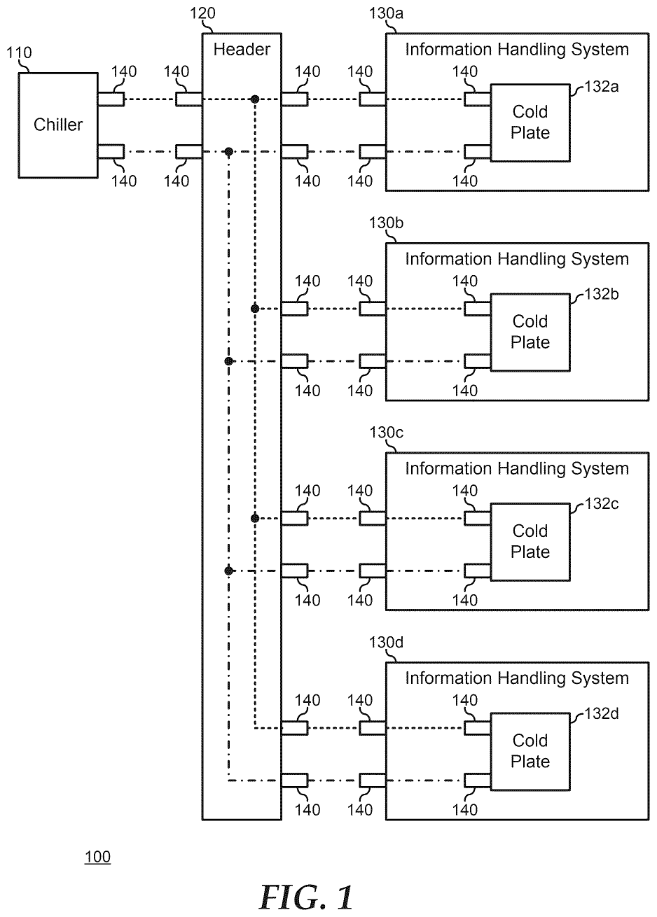

FIG. 1 illustrates a direct liquid cooling (DLC) system 100. DLC system 100 provides cooling for critical components within information handling systems, for example in a data center or other high-density computing environment. DLC system 100 includes a chiller 110, a header 120 and a number of information handling systems 130a-d. Each one of information handling systems 130a-d include one or more components that generate large amounts of heat in the enclosure of their respective information handling systems. For example information handling systems 130a-d may include one or more processors (CPUs), chipset components, graphics processing units (GPUs), memory devices, storage devices, or the like, that represent a large portion of the thermal load of the respective information handling systems.

In order to remove the heat generated in an information handling system, manufacturers and users are turning to DLC systems like DLC system 100 to more efficiently and effectively manage the heat generated within their information handling systems and data centers. In this regard, information handling systems 130a-d each include one or more cold plate 132a-d to remove the heat from the high-heat generating components. As such, chiller 110 operates to supply chilled coolant liquid (as illustrated by the dotted lines) to header 120. Header 120 includes a cold manifold that distributes the chilled coolant liquid to each of cold plates 132a-d. Cold plates 132a-d are configured to be thermally connected to the high-heat generating components, where the heat from the components is thermally transferred to the coolant liquid. The heated coolant liquid (indicated by the doted/dashed lines) is returned from cold plates 132a-d to header 120 where a cold manifold combines the heated coolant liquid for return to chiller 110. In this regard, DLC system 100 is a closed-loop system, rechilling the coolant liquid for redistribution throughout the DLC system.

DLC system 100 is characterized by the need to connect the components together to move the coolant liquid throughout the DLC system. In particular, each component (such as chiller 110, header 120, and cold plates 132a-d includes couplers 140 that couple the respective component to tubing that spans the distance between the respective components. DLC systems similar to DLC system 100 are prone to develop liquid coolant leaks. This presents a particular hazard when a leak develops within the enclosure of information handling systems 130a-d, where sensitive electronic components can be damaged, for example, when the liquid coolant bridges electrical circuits creating short circuits. Various mechanisms for mitigating liquid coolant leaks may include the application of highly absorbent material on the printed circuit boards (PCBs) of the information handling system, leak detection mechanisms such as leak detection ropes and the like, and the consequent shutting down of the information handling system when a liquid coolant leak is detected. It has been understood by the inventors of the current disclosure that couplers such as couplers 140 are more prone to develop liquid coolant leaks than are the components and tubing that are connected by the couplers.

The inventors have also understood that the coolant liquid flow in a DLC system like DLC system 100 may typically be on the order of 1.5 gallons per minute (GPM) per kilowatt (kW) of heat transferred to the coolant liquid, in order to adequately maintain the cooling of the high-heat generating components. However, a nameplate capacity DLC system that in fact provides 1.5 GPM per kW may nevertheless suffer from various impedances within the DLC system that lowers the actual flow rate to various components. For example branching of the coolant liquid flow to server multiple components (such as CPU cold plates, DIMMs, etc.), the presence of couplers and various other connectors, or clogging or residue buildup within the DLC system, or other effects may result in the lowering of the coolant liquid flow rate. Such slower coolant liquid flow rates may result in insufficient cooling of the high-heat generating components. In attrition, it has been understood that the coolant liquid flow within a DLC system occurs mainly in the middle of the channels (such as through the tubing, couplers, cold plates, or the like), and that the surfaces of the channels experience reduced flow rates of the coolant liquid, due to a boundary layer condition at the inner surface of the channels. Such boundary layer coolant liquid flow rates may be near zero, and thus the ability of the coolant liquid to remove heat from the high-heat generating components may be compromised.

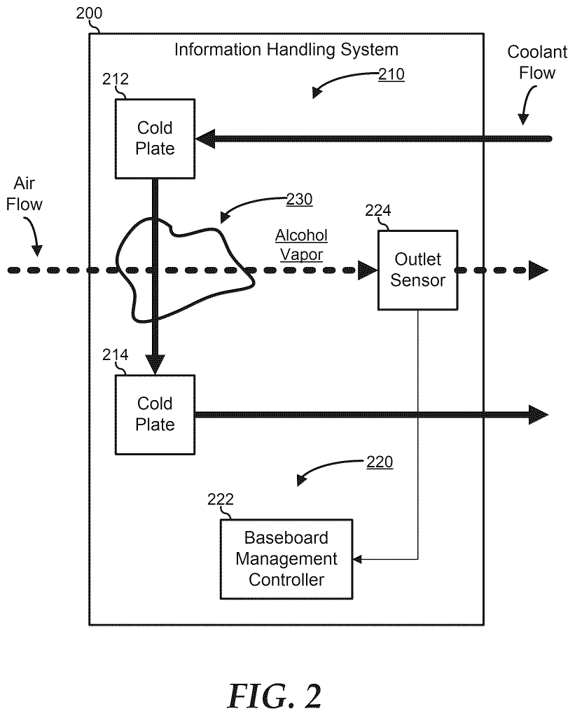

FIG. 2 illustrates an information handling system 200 including a DLC system 210 and a coolant liquid leak detection system 220. DLC system 210 includes a cold plate 212 that receives chilled coolant liquid from a chiller (not illustrated), and a cold plate 214 that receives the coolant liquid from cold plate 212 and returns the heated coolant liquid to the chiller. Leak detection system 220 includes a baseboard management controller (BMC) 222 and an outlet sensor 224. Information handling system 200 operates in with an air flow through the information handling system, typically to cool the electronic components of the information handling system that are not otherwise cooled by DLC system 210. In this regard, information handling system 200 may include one or more cooling fans that establish an air flow from a first side of the information handling system that supplies ambient or chilled air, to a second side that receives heated air from the electronic components. For example, information handling system 200 may reside in a server rack in a data center. The data center may include an air handler that provides chilled air to a cold-aisle at the front of the server rack and that evacuates heated hair from a hot-aisle at the back of the server rack.

Leak detection system 220 operates to detect leaking coolant liquid by sampling the contents of the air flow through information handling system 200 to determine whether or not the air flow contains a particular volatile compound. In this case, the coolant liquid flowing in DLC system 210 is mixed with the particular volatile compound. In this regard, the term “volatile” refers to the ability of the particular compound to easily evaporate at typical ambient temperatures of the air flow through information handling system 200. Here, outlet sensor 224 is configured to detect the presence of the particular compound in the air flow through information handling system 200. In particular when no coolant liquid is leaking in information handling system 200, outlet sensor 224 detects the absence of the volatile compound. On the other hand when coolant liquid leaks in information handling system 200, the compound mixed in the coolant liquid volatilizes in the air flow, and is detected by outlet sensor 224. An example of a volatile compound may include acetone, ethyl alcohol, isopropyl alcohol, or the like. Outlet sensor 224 is configured to detect the particular volatile compound that is mixed in the coolant liquid.

When the volatile compound is detected by outlet sensor 224, the outlet sensor provides an indication to BMC 222 of the presence of the volatile compound in the air flow in information handling system 200, and thereby detects the presence of a coolant liquid leak. BMC 222 operates to provide mitigating actions for information handling system 200, such as by shutting down the information handling system, informing a data center management system of the presence of the coolant liquid leak, or the like. The remedial actions in response to leaking coolant liquid in an information handling system are known in the art and will not be described further herein, except as may be needed to illustrate the current embodiments.

In a particular embodiment, outlet sensor 224 operates as a bi-state sensor, providing a first output (such as a logic “0” state) in the absence of the volatile compound, and a second output (such as a logic “1” state) when the presence of the volatile compound exceeds a detection threshold of the output sensor. In this case, BMC 222 may merely be provided with information as to the presence or absence of leaking coolant liquid in information handling system 200. In another embodiment, outlet sensor 224 operates as a variable output sensor, providing a spectrum of output states, each output state correlating to a particular level of compound detected in the air flow. For example, output sensor 224 may provide a variable voltage, where a low voltage correlates with no detected compound, and where increasing voltage levels correlate to increasing amounts of detected compound. In another example, output sensor 224 may operate to encode a detected amount of compound and to send the coded detection information to BMC 222, for example, over a 2-wire interface such as an I2C interface or the like.

In this case, BMC 222 may provide graded responses to the detected presence of the compound. For example a low-level detection of the compound may indicate a minor leak that may be deemed to be requiring of an indication to the data center management system, but not of shutting down information handling system 200. On the other hand, a mid-level detection may indicate a more significant leak that may be deemed to require shutting down information handling system 200. Finally, a high-level detection may indicate a major leak that risks flowing into adjacent information handling systems in a server rack that may require shutting down all information handling systems in the server racks.

Leak detection system 220 is illustrated as including BMC 222. It will be understood that the use of a BMC is for illustrative purposes, and that such use may provide advantages in the overall operation of information handling system 200 within, for example, a data center, and to the operation of the data center itself. However including BMC 222 should not be understood as limiting the scope of the current embodiments. In particular, a sensor similar to outlet sensor 224 may provide its leak detection information to a BMC, to a microcontroller, to a CPU of the information handling system, to a dedicated leak detection circuit instantiated on the information handling system, or on any other type of logic or control element to provide the functions and features as described herein.

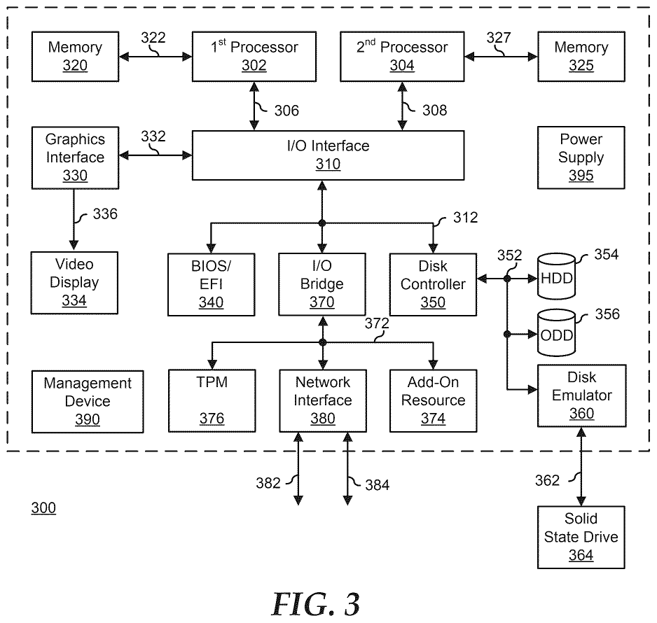

FIG. 3 illustrates a generalized embodiment of an information handling system 300 similar to information handling system 300. For purpose of this disclosure an information handling system can include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, information handling system 300 can be a personal computer, a laptop computer, a smart phone, a tablet device or other consumer electronic device, a network server, a network storage device, a switch router or other network communication device, or any other suitable device and may vary in size, shape, performance, functionality, and price. Further, information handling system 300 can include processing resources for executing machine-executable code, such as a central processing unit (CPU), a programmable logic array (PLA), an embedded device such as a System-on-a-Chip (SoC), or other control logic hardware. Information handling system 300 can also include one or more computer-readable medium for storing machine-executable code, such as software or data. Additional components of information handling system 300 can include one or more storage devices that can store machine-executable code, one or more communications ports for communicating with external devices, and various input and output (I/O) devices, such as a keyboard, a mouse, and a video display. Information handling system 300 can also include one or more buses operable to transmit information between the various hardware components.

Information handling system 300 can include devices or modules that embody one or more of the devices or modules described below, and operates to perform one or more of the methods described below. Information handling system 300 includes a processors 302 and 304, an input/output (I/O) interface 310, memories 320 and 325, a graphics interface 330, a basic input and output system/universal extensible firmware interface (BIOS/UEFI) module 340, a disk controller 350, a hard disk drive (HDD) 354, an optical disk drive (ODD) 356, a disk emulator 360 connected to an external solid state drive (SSD) 362, an I/O bridge 370, one or more add-on resources 374, a trusted platform module (TPM) 376, a network interface 380, a management device 390, and a power supply 395. Processors 302 and 304, I/O interface 310, memory 320, graphics interface 330, BIOS/UEFI module 340, disk controller 350, HDD 354, ODD 356, disk emulator 360, SSD 362, I/O bridge 370, add-on resources 374, TPM 376, and network interface 380 operate together to provide a host environment of information handling system 300 that operates to provide the data processing functionality of the information handling system. The host environment operates to execute machine-executable code, including platform BIOS/UEFI code, device firmware, operating system code, applications, programs, and the like, to perform the data processing tasks associated with information handling system 300.

In the host environment, processor 302 is connected to I/O interface 310 via processor interface 306, and processor 304 is connected to the I/O interface via processor interface 308. Memory 320 is connected to processor 302 via a memory interface 322. Memory 325 is connected to processor 304 via a memory interface 327. Graphics interface 330 is connected to I/O interface 310 via a graphics interface 332, and provides a video display output 336 to a video display 334. In a particular embodiment, information handling system 300 includes separate memories that are dedicated to each of processors 302 and 304 via separate memory interfaces. An example of memories 320 and 330 include random access memory (RAM) such as static RAM (SRAM), dynamic RAM (DRAM), non-volatile RAM (NV-RAM), or the like, read only memory (ROM), another type of memory, or a combination thereof.

BIOS/UEFI module 340, disk controller 350, and I/O bridge 370 are connected to I/O interface 310 via an I/O channel 312. An example of I/O channel 312 includes a Peripheral Component Interconnect (PCI) interface, a PCI-Extended (PCI-X) interface, a high-speed PCI-Express (PCIe) interface, another industry standard or proprietary communication interface, or a combination thereof. I/O interface 310 can also include one or more other I/O interfaces, including an Industry Standard Architecture (ISA) interface, a Small Computer Serial Interface (SCSI) interface, an Inter-Integrated Circuit (I²C) interface, a System Packet Interface (SPI), a Universal Serial Bus (USB), another interface, or a combination thereof. BIOS/UEFI module 340 includes BIOS/UEFI code operable to detect resources within information handling system 300, to provide drivers for the resources, initialize the resources, and access the resources. BIOS/UEFI module 340 includes code that operates to detect resources within information handling system 300, to provide drivers for the resources, to initialize the resources, and to access the resources.

Disk controller 350 includes a disk interface 352 that connects the disk controller to HDD 354, to ODD 356, and to disk emulator 360. An example of disk interface 352 includes an Integrated Drive Electronics (IDE) interface, an Advanced Technology Attachment (ATA) such as a parallel ATA (PATA) interface or a serial ATA (SATA) interface, a SCSI interface, a USB interface, a proprietary interface, or a combination thereof. Disk emulator 360 permits SSD 364 to be connected to information handling system 300 via an external interface 362. An example of external interface 362 includes a USB interface, an IEEE 1394 (Firewire) interface, a proprietary interface, or a combination thereof. Alternatively, solid-state drive 364 can be disposed within information handling system 300.

I/O bridge 370 includes a peripheral interface 372 that connects the I/O bridge to add-on resource 374, to TPM 376, and to network interface 380. Peripheral interface 372 can be the same type of interface as I/O channel 312, or can be a different type of interface. As such, I/O bridge 370 extends the capacity of I/O channel 312 where peripheral interface 372 and the I/O channel are of the same type, and the I/O bridge translates information from a format suitable to the I/O channel to a format suitable to the peripheral channel 372 where they are of a different type. Add-on resource 374 can include a data storage system, an additional graphics interface, a network interface card (NIC), a sound/video processing card, another add-on resource, or a combination thereof. Add-on resource 374 can be on a main circuit board, on separate circuit board or add-in card disposed within information handling system 300, a device that is external to the information handling system, or a combination thereof.

Network interface 380 represents a NIC disposed within information handling system 300, on a main circuit board of the information handling system, integrated onto another component such as I/O interface 310, in another suitable location, or a combination thereof. Network interface device 380 includes network channels 382 and 384 that provide interfaces to devices that are external to information handling system 300. In a particular embodiment, network channels 382 and 384 are of a different type than peripheral channel 372 and network interface 380 translates information from a format suitable to the peripheral channel to a format suitable to external devices. An example of network channels 382 and 384 includes InfiniBand channels, Fibre Channel channels, Gigabit Ethernet channels, proprietary channel architectures, or a combination thereof. Network channels 382 and 384 can be connected to external network resources (not illustrated). The network resource can include another information handling system, a data storage system, another network, a grid management system, another suitable resource, or a combination thereof.

Management device 390 represents one or more processing devices, such as a dedicated baseboard management controller (BMC) System-on-a-Chip (SoC) device, one or more associated memory devices, one or more network interface devices, a complex programmable logic device (CPLD), and the like, that operate together to provide the management environment for information handling system 300. In particular, management device 390 is connected to various components of the host environment via various internal communication interfaces, such as a Low Pin Count (LPC) interface, an Inter-Integrated-Circuit (I2C) interface, a PCIe interface, or the like, to provide an out-of-band (OOB) mechanism to retrieve information related to the operation of the host environment, to provide BIOS/UEFI or system firmware updates, to manage non-processing components of information handling system 300, such as system cooling fans and power supplies. Management device 390 can include a network connection to an external management system, and the management device can communicate with the management system to report status information for information handling system 300, to receive BIOS/UEFI or system firmware updates, or to perform other task for managing and controlling the operation of information handling system 300. Management device 390 can operate off of a separate power plane from the components of the host environment so that the management device receives power to manage information handling system 300 where the information handling system is otherwise shut down. An example of management device 390 include a commercially available BMC product or other device that operates in accordance with an Intelligent Platform Management Initiative (IPMI) specification, a Web Services Management (WSMan) interface, a Redfish Application Programming Interface (API), another Distributed Management Task Force (DMTF), or other management standard, and can include an Integrated Dell Remote Access Controller (iDRAC), an Embedded Controller (EC), or the like. Management device 390 may further include associated memory devices, logic devices, security devices, or the like, as needed or desired.

Although only a few exemplary embodiments have been described in detail herein, those skilled in the art will readily appreciate that many modifications are possible in the exemplary embodiments without materially departing from the novel teachings and advantages of the embodiments of the present disclosure. Accordingly, all such modifications are intended to be included within the scope of the embodiments of the present disclosure as defined in the following claims. In the claims, means-plus-function clauses are intended to cover the structures described herein as performing the recited function and not only structural equivalents, but also equivalent structures.

The above-disclosed subject matter is to be considered illustrative, and not restrictive, and the appended claims are intended to cover any and all such modifications, enhancements, and other embodiments that fall within the scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed:

1. An information handling system, comprising:
a liquid cooling system configured to cool a component of the information handling system, the liquid cooling system including a coolant liquid having a volatile compound mixed therein; and
a leak detection system configured to detect a leak of the coolant liquid by detecting a presence of the volatile compound.

2. The information handling system of claim 1, wherein the leak detection system includes a sensor located within an air flow in the information handling system, the leak sensor configured to detect the volatile compound.

3. The information handling system of claim 2, wherein the sensor is located within the air flow at a location to detect the coolant liquid leak at a location that is upstream in the air flow from the sensor.

4. The information handling system of claim 3, wherein the sensor is located at an outlet of the air flow from the information handling system.

5. The information handling system of claim 2, wherein the sensor is configured to detect the presence of the volatile compound.

6. The information handling system of claim 5, wherein the sensor is configured to provide an output at a first state when the volatile compound is not detected, and to provide the output at a second state when the volatile compound is detected.

7. The information handling system of claim 5, wherein the sensor is configured to provide a variable output that is correlated to an amount of the volatile compound detected by the sensor.

8. The information handling system of claim 2, wherein the leak detection system further includes a baseboard management controller (BMC) configured to receive an indication of a detection of the volatile compound from the sensor.

9. The information handling system of claim 8, wherein the BMC is further configured to halt an operation of the information handling system in response to the detection of the volatile compound.

10. The information handling system of claim 1, wherein the volatile compound includes one of an alcohol compound and an acetone compound.

11. A method, comprising:
providing, in an information handling system, a liquid cooling system configured to cool a component of the information handling system, the liquid cooling system including a coolant liquid having a volatile compound mixed therein;
providing, in the information handling system, a leak detection system; and
detecting, by the leak detection system, a leak of the coolant liquid by detecting a presence of the volatile compound.

12. The method of claim 11, further comprising:
providing, in the leak detection system, a sensor located within an air flow in the information handling system, the leak sensor configured to detect the volatile compound.

13. The method of claim 12, wherein the sensor is located within the air flow at a location to detect the coolant liquid leak at a location that is upstream in the air flow from the sensor.

14. The method of claim 13, wherein the sensor is located at an outlet of the air flow from the information handling system.

15. The method of claim 12, wherein the sensor is configured to detect the presence of the volatile compound.

16. The method of claim 15, wherein the sensor is configured to provide an output at a first state when the volatile compound is not detected, and to provide the output at a second state when the volatile compound is detected.

17. The method of claim 15, wherein the sensor is configured to provide a variable output that is correlated to an amount of the volatile compound detected by the sensor.

18. The method of claim 12, further comprising:
providing, in the leak detection system, a baseboard management controller (BMC) configured to receive an indication of a detection of the volatile compound from the sensor.

19. The information handling system of claim 7, wherein the BMC is further configured to halt an operation of the information handling system in response to a detection of the volatile compound.

20. A leak detection system for detecting a coolant liquid leak in an information handling system, the leak detection system comprising:
a sensor located within an air flow in the information handling system, the sensor configured to detect a volatile compound included in the coolant liquid; and
a baseboard management controller (BMC) configured to receive an indication of a detection of the volatile compound from the sensor, wherein the volatile compound includes an alcohol compound.
